(19) United States
(12) Patent Application Publication
(10) Pub. No.: US 2023/0246076 A1
(43) Pub. Date: Aug. 3, 2023

(54) SILICON CARBIDE SEMICONDUCTOR DEVICE AND METHOD OF MANUFACTURING SILICON CARBIDE SEMICONDUCTOR DEVICE

(71) Applicant: FUJI ELECTRIC CO., LTD., Kawasaki-shi (JP)

(72) Inventors: Masakazu BABA, Matsumoto-city (JP); Shinsuke HARADA, Tsukuba-city (JP)

(73) Assignee: FUJI ELECTRIC CO., LTD., Kawasaki-shi (JP)

(21) Appl. No.: 18/158,318

(22) Filed: Jan. 23, 2023

(30) Foreign Application Priority Data
Jan. 31, 2022 (JP) 2022-012506

(51) Int. Cl. H01L 29/16; H01L 29/423; H01L 29/78; H01L 29/10; H01L 29/66; H01L 21/265

(52) U.S. Cl. CPC H01L 29/1608; H01L 29/4236; H01L 29/7813; H01L 29/1095; H01L 29/66712; H01L 29/66068; H01L 21/26506

(57) ABSTRACT

By a first ion-implantation of a p-type impurity, first and second p⁺-type regions for mitigating electric field of trench bottoms are formed in surface regions of an n⁻-type epitaxial layer that constitutes an n⁻-type drift region. Thereafter, a second ion-implantation of an n-type impurity for reverting a portion of each of the first p⁺-type regions to the n⁻-type, and a third ion-implantation of an n-type impurity for an entire surface of the n⁻-type epitaxial layer, are performed. By the second ion-implantation, first current spreading layer (CSL) portions that constituting n-type current spreading regions are formed facing the first p⁺-type regions in the depth direction. By the third ion-implantation, the first CSL portions have a predetermined n-type impurity concentration, and second CSL portions constituting the n-type current spreading regions are formed between the first and second p⁺-type regions and are in contact with the first CSL portions.

### CROSS REFERENCE TO RELATED APPLICATIONS

This application is based upon and claims the benefit of priority of the prior Japanese Patent Application No. 2022-012506, filed on Jan. 31, 2022, the entire contents of which are incorporated herein by reference.

### BACKGROUND OF THE INVENTION

### 1. Field of the Invention

Embodiments of the invention relate to a silicon carbide semiconductor device and a method of manufacturing a silicon carbide semiconductor device.

### 2. Description of the Related Art

In a conventionally known method of manufacturing a metal oxide semiconductor field effect transistor (MOSFET) containing silicon carbide (SiC) as a semiconductor material (SiC-MOSFET) and having insulated gates with a three-layer structure including a metal, an oxide film, and a semiconductor, when epitaxial layers respectively constituting an n⁻-type drift region and a p-type base region are sequentially deposited on a front surface of an n⁺-type starting substrate containing silicon carbide, diffused regions for mitigating electric field and MOS gates (insulated gates with a three-layer structure including a metal, an oxide film, and a semiconductor) are formed each time one of the epitaxial layers is deposited.

FIGS. 20, 21, 22, 23, 24, 25, 26, and 27 are cross-sectional views depicting states of a conventional silicon carbide semiconductor device during manufacture. A conventional silicon carbide semiconductor device 110 (refer to FIG. 27) is a vertical SiC-MOSFET with a trench structure, first and second p⁻-type regions 121, 122 that mitigate electric field applied to bottoms of trenches 107 configuring the trench structure, and an n-type current spreading region 103 that reduces carrier spreading resistance. In the fabrication of the conventional silicon carbide semiconductor device 110, first, as depicted in FIG. 20, an n⁻-type epitaxial layer 132 is epitaxially grown on an n⁺-type starting substrate 131 that contains silicon carbide and constitutes an n⁺-type drain region 101.

Next, as depicted in FIG. 21, by photolithography and a first ion-implantation of aluminum (Al), the first p⁺-type regions 121 and p⁺-type regions 122a are each selectively formed at positions apart from one another in the n⁻-type epitaxial layer 132, at the surface of the n⁻-type epitaxial layer 132. The first p⁺-type regions 121 are formed at positions that face, in a depth direction, the bottoms of the trenches 107 formed by a later process. The p⁺-type regions 122a are portions of the second p⁺-type regions 122 Between the trenches 107 that are adjacent to one another, the second p⁺-type regions 122 are formed at positions apart from the trenches 107 and the first p⁺-type regions 121 and are in contact with a p-type base region 104 formed by a later process.

Next, as depicted in FIG. 22, after an ion implantation mask (not depicted) used in forming the first p⁺-type regions 121 and the p⁺-type regions 122a is removed, n-type regions 103a are formed in the n⁻-type epitaxial layer 132, at the surface of the n⁻-type epitaxial layer 132, by photolithography and a second ion-implantation of nitrogen (N). The n-type regions 103a are between and in contact with the first p⁺-type regions 121 and the p⁺-type regions 122a. The n-type regions 103a are portions of the n-type current spreading region 103. A portion of the n⁻-type epitaxial layer 132, excluding the n-type regions 103a, the first p⁺-type regions 121, and the p⁺-type regions 122a constitutes an n⁻-type drift region 102.

Next, as depicted in FIG. 23, after an ion implantation mask (not depicted) used in forming the n-type regions 103a is removed, an n⁻-type epitaxial layer is epitaxially grown on the n⁻-type epitaxial layer 132, thereby, increasing a thickness of the n⁻-type epitaxial layer 132. Next, as depicted in FIG. 24, by photolithography and a third ion-implantation of aluminum, in a portion 132a that increases the thickness of the n⁻-type epitaxial layer 132, p⁺-type regions 122b are selectively formed to depths reaching the p⁺-type regions 122a. The p⁺-type regions 122a, 122b adjacent to one another in the depth direction are connected, thereby, forming the second p⁺-type regions 122.

Next, as depicted in FIG. 25, after an ion implantation mask (not depicted) used in forming the p⁺-type regions 122b is removed, n-type regions 103b are formed in the portion 132a that increases the thickness of the n⁻-type epitaxial layer 132, the n-type regions 103b being formed to a depth reaching the n-type regions 103a, by photolithography and a fourth ion-implantation of nitrogen. The n-type regions 103a, 103b adjacent to one another in the depth direction are connected, thereby, forming the n-type current spreading region 103. Next, as depicted in FIG. 26, after an ion implantation mask (not depicted) used in forming the n-type regions 103b is removed, a p-type epitaxial layer 133 is epitaxially grown on the n⁻-type epitaxial layer 132.

Thus, a semiconductor substrate 130 in which the n⁻-type epitaxial layer 132 and the p-type epitaxial layer 133 are sequentially stacked on the n⁺-type starting substrate 131 is formed. In this manner, the semiconductor substrate 130 is formed by seven processes (the epitaxial growth of the n⁻-type epitaxial layer 132, the first and second ion-implantations, the epitaxial growth for increasing the thickness of the n⁻-type epitaxial layer 132, the third and fourth ion-implantations, and the epitaxial growth of the p-type epitaxial layer 133) from the process of epitaxially growing the n⁻-type epitaxial layer 132 to the process of epitaxially growing the p-type epitaxial layer 133.

Next, as depicted in FIG. 27, by a general method, MOS gates of the trench structure configured by n⁺-type source regions 105, p⁺⁺-type contact regions 106, the trenches 107, gate insulating films 108, and gate electrodes 109 are formed in the semiconductor substrate 130, in a side thereof having the p-type epitaxial layer 133. A portion of the p-type epitaxial layer 133, excluding the n⁺-type source regions 105 and the p⁺⁺-type contact regions 106, constitutes the p-type base region 104. Reference numeral 111 is an interlayer insulating film. Subsequently, at both main surfaces of the semiconductor substrate 130, a source electrode 112 and a drain electrode 113 are formed, respectively, thereby, completing the SiC-MOSFET.

As a method of manufacturing a conventional silicon carbide semiconductor device, a method of manufacturing has been proposed for a SiC-MOSFET with a trench structure that includes an n-type current spreading region, p⁺-type regions directly beneath trenches for mitigating electric field of the trench bottoms and p⁺-type regions between the trenches for mitigating the electric field of the trench bottoms, and according to the method, the n-type current spreading region has a predetermined thickness obtained by two epitaxial growth processes, and each time an epitaxial layer constituting the n-type current spreading region is deposited, a p-type impurity is selectively ion-implanted in the epitaxial layer, thereby, forming the p⁺-type regions for mitigating the electric field of the trench bottoms (for example, refer to Japanese Laid-Open Patent Publication No. 2019-106483, Japanese Laid-Open Patent Publication No. 2019-102737, and Japanese Laid-Open Patent Publication No. 2018-019046).

### SUMMARY OF THE INVENTION

According to an embodiment of the present invention, a method of manufacturing a vertical silicon carbide semiconductor device having a trench structure, includes: as a first process, preparing a starting substrate that contains silicon carbide, the starting substrate having a main surface, and forming a first-conductivity-type epitaxial layer, which is an epitaxial layer of a first conductivity type, on the main surface of the starting substrate, the first-conductivity-type epitaxial layer having a first surface and a second surface that are opposite to each other, the second surface facing the starting substrate; as a second process, performing a first ion-implantation of an impurity of a second conductivity type and thereby forming, in the first-conductivity-type epitaxial layer, a plurality of second-conductivity-type high-concentration regions at the first surface of the first-conductivity-type epitaxial layer; as a third process, forming, in the first-conductivity-type epitaxial layer, a plurality of current spreading regions of the first conductivity type at the first surface of the first-conductivity-type epitaxial layer, the plurality of current spreading regions reducing carrier spreading resistance and having an impurity concentration that is higher than an impurity concentration of the first-conductivity-type epitaxial layer; as a fourth process, forming a second-conductivity-type epitaxial layer, which is an epitaxial layer of a second conductivity type, on the first surface of the first-conductivity-type epitaxial layer, after forming the plurality of second-conductivity-type high-concentration regions and the plurality of current spreading regions; and as a fifth process, forming the trench structure in the second-conductivity-type epitaxial layer, the trench structure including a plurality of trenches. The plurality of second-conductivity-type high-concentration regions includes a plurality of first second-conductivity-type high-concentration regions and a plurality of second second-conductivity-type high-concentration regions. The second process includes: forming the plurality of first second-conductivity-type high-concentration regions respectively in a plurality of formation regions of the plurality of trenches, each of the plurality of first second-conductivity-type high-concentration regions reaching a first position that is closer to the starting substrate than are the plurality of trenches, and having a first surface and a second surface that are opposite to each other, the second surface thereof facing the starting substrate, and forming the plurality of second second-conductivity-type high-concentration regions, each between adjacent two of the plurality of formation regions of the plurality of trenches and reaching a second position that is closer to the starting substrate than are the plurality of trenches. The plurality of current spreading regions includes a plurality of first current spreading regions and a plurality of second current spreading regions. The third process includes: as a first implantation process, performing a second ion-implantation of an impurity of the first conductivity type and thereby increasing, in the plurality of first second-conductivity-type high-concentration regions, a first-conductivity-type impurity concentration of surface portions at the first surfaces of the plurality of first second-conductivity-type high-concentration regions to be higher than a second-conductivity-type impurity concentration thereof, thereby forming the plurality of first current spreading regions, each of the plurality of first current spreading regions being formed between the first surface of the first-conductivity-type epitaxial layer and a remaining portion of each of the plurality of first second-conductivity-type high-concentration regions, the remaining portion being free of the second ion-implantation, and as a second implantation process, performing a third ion-implantation of the impurity of the first conductivity type in an entire area of the first surface of the first-conductivity-type epitaxial layer, thereby increasing the first-conductivity-type impurity concentration of the surface portions that constitute the plurality of first current spreading regions, to be higher than the second-conductivity-type impurity concentration, and further forming the plurality of second current spreading regions in the first-conductivity-type epitaxial layer, in portions thereof at the first surface of the first-conductivity-type epitaxial layer, excluding the plurality of second-conductivity-type high-concentration regions and the plurality of first current spreading regions, the plurality of second current spreading regions being in contact with the plurality of first current spreading regions.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view depicting a structure of a silicon carbide semiconductor device according to a first embodiment.

FIG. 2 is a cross-sectional view showing a portion of impurity concentration distribution in FIG. 1.

FIG. 3 is a characteristics diagram showing an impurity concentration distribution obtained by first to third ion-implantations for forming a portion in FIG. 1.

FIG. 4 is a table showing an example of multistage ion implantation conditions for obtaining the impurity concentration distribution in FIG. 3.

FIG. 5 is a cross-sectional view depicting a state of the silicon carbide semiconductor device according to the first embodiment during manufacture.

FIG. 6 is a cross-sectional view depicting a state of the silicon carbide semiconductor device according to the first embodiment during manufacture.

FIG. 7 is a cross-sectional view depicting a state of the silicon carbide semiconductor device according to the first embodiment during manufacture.

FIG. 8 is a cross-sectional view depicting a state of the silicon carbide semiconductor device according to the first embodiment during manufacture.

FIG. 9 is a cross-sectional view depicting a state of the silicon carbide semiconductor device according to the first embodiment during manufacture.

FIG. 10 is a cross-sectional view depicting a state of the silicon carbide semiconductor device according to the first embodiment during manufacture.

FIG. 11 is a cross-sectional view depicting another example of the state in FIG. 7 during manufacturing.

FIG. 12 is a cross-sectional view depicting another example of a state of a comparison example during manufacture.

FIG. 13 is a cross-sectional view depicting another example of a state of a comparison example during manufacture.

FIG. 14 is a plan view of the state in FIG. 6 as viewed from an ion-implantation surface.

FIG. 15 is a plan view of the state in FIG. 7 as viewed from an ion-implantation surface.

FIG. 16 is a plan view of the state in FIG. 8 as viewed from an ion-implantation surface.

FIG. 17 is a cross-sectional view depicting a state of a silicon carbide semiconductor device according to a second embodiment during manufacture.

FIG. 18 is a cross-sectional view depicting a state of the silicon carbide semiconductor device according to the second embodiment during manufacture.

FIG. 19 is a cross-sectional view depicting a state of the silicon carbide semiconductor device according to the second embodiment during manufacture.

FIG. 20 is a cross-sectional view depicting a state of a conventional silicon carbide semiconductor device during manufacture.

FIG. 21 is a cross-sectional view depicting a state of the conventional silicon carbide semiconductor device during manufacture.

FIG. 22 is a cross-sectional view depicting a state of the conventional silicon carbide semiconductor device during manufacture.

FIG. 23 is a cross-sectional view depicting a state of the conventional silicon carbide semiconductor device during manufacture.

FIG. 24 is a cross-sectional view depicting a state of the conventional silicon carbide semiconductor device during manufacture.

FIG. 25 is a cross-sectional view depicting a state of the conventional silicon carbide semiconductor device during manufacture.

FIG. 26 is a cross-sectional view depicting a state of the conventional silicon carbide semiconductor device during manufacture.

FIG. 27 is a cross-sectional view depicting a state of the conventional silicon carbide semiconductor device during manufacture.

### DETAILED DESCRIPTION OF THE INVENTION

First, problems associated with the conventional techniques are discussed. As described above, in the method of manufacturing the conventional silicon carbide semiconductor device 110 (refer to FIG. 27), it is problematic that the first and second p⁺-type regions 121, 122 and the n-type current spreading region 103 in the n⁻-type epitaxial layer 132 are formed by a large number of processes, i.e., seven processes, from the process of epitaxially growing the n⁻-type epitaxial layer 132 to epitaxially growing the p-type epitaxial layer 133.

Embodiments of a silicon carbide semiconductor device and a method of manufacturing a silicon carbide semiconductor device according to the present invention will be described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or −. In the description of the embodiments below and the accompanying drawings, main portions that are identical are given the same reference numerals and are not repeatedly described.

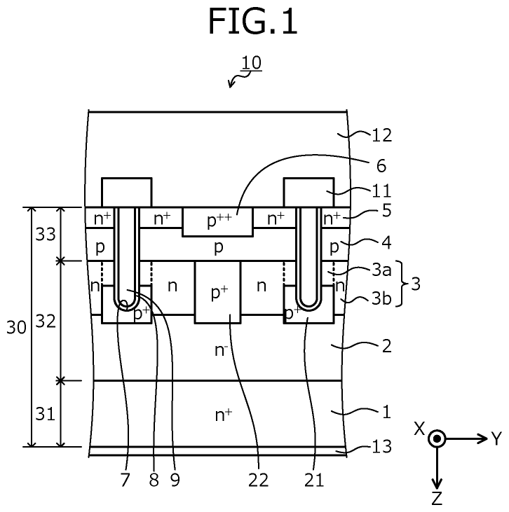

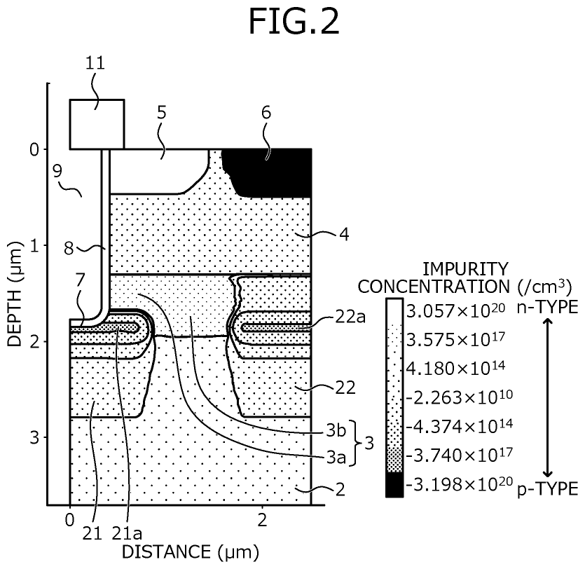

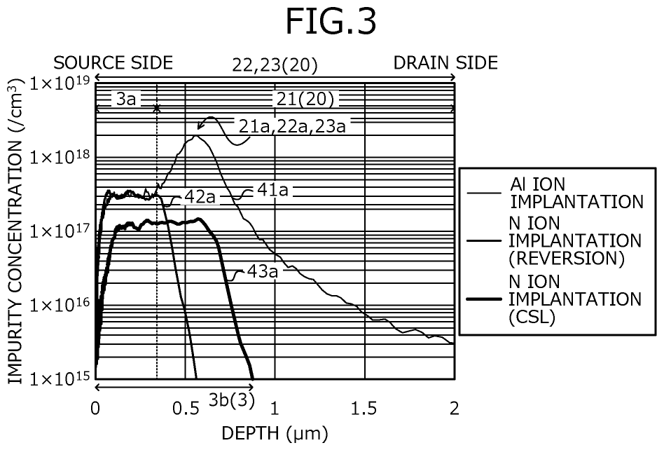

A structure of a silicon carbide semiconductor device according to a first embodiment is described. FIG. 1 is a cross-sectional view depicting the structure of the silicon carbide semiconductor device according to the first embodiment. FIG. 2 is a cross-sectional view showing a portion of impurity concentration distribution in FIG. 1. FIG. 3 is a characteristics diagram showing an impurity concentration distribution obtained by first to third ion-implantations for forming a portion in FIG. 1. In FIGS. 2 and 3, impurity concentration distributions of first and second p⁺-type regions (first and second second-conductivity-type high-concentration regions) 21, 22 and n-type current spreading regions 3 in FIG. 1 are indicated by dotted hatching. In FIG. 2, a legend indicates n-type impurity concentrations as positive values and p-type impurity concentrations as negative values. In FIG. 3, a depth=0 μm on a horizontal axis indicates an interface between a p-type base region 4 and, the n-type current spreading regions 3 and the second p⁺-type regions 22.

The silicon carbide semiconductor device 10 according to the first embodiment depicted in FIG. 1 is a vertical SiC-MOSFET having a trench structure and in an active region, in a semiconductor substrate (semiconductor chip) 30 that contains silicon carbide (SiC) as a semiconductor material, has first to third p⁺-type regions 21 to 23 that mitigate electric field applied to bottoms of trenches 7 that configure the trench structure, and the n-type current spreading regions 3 that reduce carrier spreading resistance. In the semiconductor substrate 30, epitaxial layers (first-conductivity-type and second-conductivity-type epitaxial layers) 32, 33 constituting an n⁻-type drift region (first semiconductor region) 2 and the p-type base region (second semiconductor region) 4 are sequentially stacked on a front surface of an n⁺-type starting substrate 31 that contains silicon carbide as a semiconductor material.

The active region is a region through which a main current passes when the SiC-MOSFET is in an on-state and disposed in the active region are multiple adjacent unit cells (functional units of the device) of the SiC-MOSFET. An edge termination region (not depicted) surrounds a periphery of the active region. The edge termination region is a region between the active region and an end (chip end) of the semiconductor substrate 30, the edge termination region mitigating electric field of a front side of the semiconductor substrate 30 and sustaining the breakdown voltage. In the edge termination region, a voltage withstanding structure such as a field limiting ring (FLR) or junction termination extension (JTE) structure is disposed.

The semiconductor substrate 30 has, as a front surface, a main surface having the p-type epitaxial layer 33 and, as a back surface, a main surface having the n⁺-type starting substrate 31 (back surface of the n⁺-type starting substrate 31). A crystal structure of the semiconductor substrate 30, for example, may be a four-layer periodic hexagonal silicon carbide crystal (4H-SiC). The n⁺-type starting substrate 31 constitutes an n⁺-type drain region 1. The n⁻-type drift region 2 is a portion of the n⁻-type epitaxial layer 32, excluding the later-described first to third p⁺-type regions 21 to 23 and the later-described n-type current spreading regions 3. The n⁻-type drift region 2 is provided between and in contact with the first to third p⁺-type regions 21 to 23 and the n-type current spreading regions 3 and the n⁺-type starting substrate 31.

The p-type base region 4 is a portion of the p-type epitaxial layer 33, excluding later-described n⁺-type source regions (plurality of third semiconductor regions) 5 and later-described p⁺⁺-type contact regions 6. The p-type base region 4 is provided between the front surface of the semiconductor substrate 30 and the n⁻-type drift region 2, in the active region. The first to third p⁺-type regions 21 to 23 and the n-type current spreading regions 3 are each selectively provided between the p-type base region 4 and the n⁻-type drift region 2. The first to third p⁺-type regions 21 to 23 and the n-type current spreading regions 3 are diffused regions formed by ion implantation in the n⁻-type epitaxial layer 32, at the surface of the n⁻-type epitaxial layer 32.

The first p⁺-type regions 21 are provided apart from the p-type base region 4 and reach deep positions closer to a drain electrode 13 than are the bottoms of the trenches 7; the first p⁺-type regions 21 face the bottoms of the trenches 7, respectively, in a depth direction Z. The first p⁺-type regions 21 surround the bottoms of the trenches 7, respectively, and are exposed at the bottoms of the trenches 7. Being exposed at the bottoms of the trenches 7 means being in contact with later-described gate insulating films 8 at the bottoms of the trenches 7. The second p⁺-type regions 22 are provided between the trenches 7 that are adjacent to one another, the second p⁺-type regions 22 being in contact with the p-type base region 4 but apart from the first p⁺-type regions 21 and the trenches 7. The second p⁺-type regions 22 reach deep positions closer to the drain electrode 13 than are the bottoms of the trenches 7.

The first p⁺-type regions 21 and the second p⁺-type regions 22 extend linearly in a later-described first direction X that is a same direction in which the trenches 7 extend in a striped pattern, the first p⁺-type regions 21 and the second p⁺-type regions 22 being disposed to repeatedly alternate one another in a second direction Y that is parallel to the front surface of the semiconductor substrate 30 and orthogonal to the first direction X. The first and second p⁻-type regions 21, 22 are electrically connected to one another by the third p⁻-type regions 23 (FIGS. 14 to 16). The first and second p⁺-type regions 21, 22 are electrically connected to a source electrode 12 and fixed to a source potential; the first and second p⁺-type regions 21, 22 have a function of depleting when the SiC-MOSFET is off and mitigating the electric field applied to the bottoms of the trenches 7.

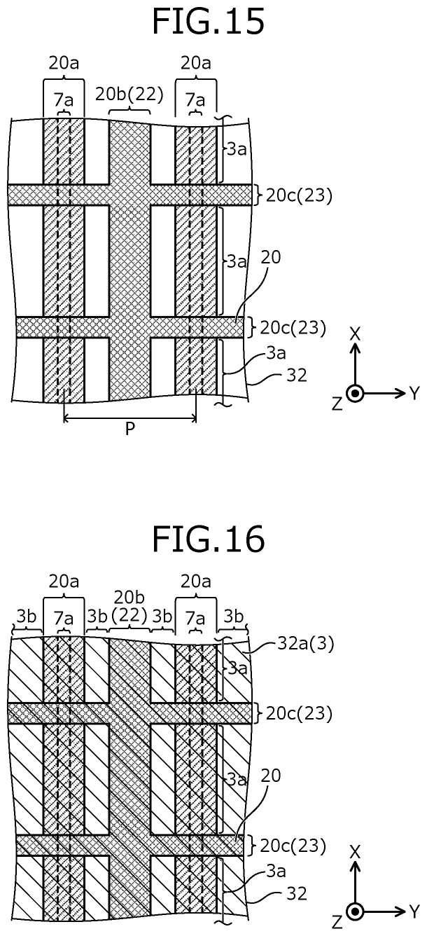

Between the first and second p⁺-type regions 21, 22 that are adjacent to one another, the third p⁺-type regions 23 are provided in contact with the first and second p⁺-type regions 21, 22, and the p-type base region 4. The third p⁻-type regions 23, for example, extend in a striped pattern in the second direction Y and may be connected to the first and second p⁺-type regions 21, 22 at locations where the p⁺-type regions 23 intersect with the first and second p⁻-type regions 21, 22. In this instance, a single p⁺-type region 20 (second-conductivity-type high-concentration regions, refer to FIG. 15) constituted by the first to third p⁺-type regions 21 to 23 is disposed in a lattice-like shape as viewed from the front side of the semiconductor substrate 30. The third p⁺-type regions 23 may reach deep positions closer to the drain electrode 13 than are the bottoms of the trenches 7.

The first to third p⁺-type regions 21 to 23 are, respectively, portions 20a, 20b, and 20c of the p⁺-type region 20, formed concurrently by a later-described first ion-implantation 41 (corresponds to Al ion implantation in FIG. 3, refer to FIGS. 6 and 14). A p-type impurity concentration distribution 41a of the first to third p⁺-type regions 21 to 23 exhibits a maximum value (peak concentration) at a deep position closer to the drain electrode 13 (drain) than are the bottoms of the trenches 7, and has a mountain-like shaped impurity concentration distribution in which the impurity concentration decreases from depth positions (peak positions) 21a, 22a, 23a of the peak concentrations, in directions to the source electrode 12 (source) and to the drain (refer to FIGS. 2 and 3).

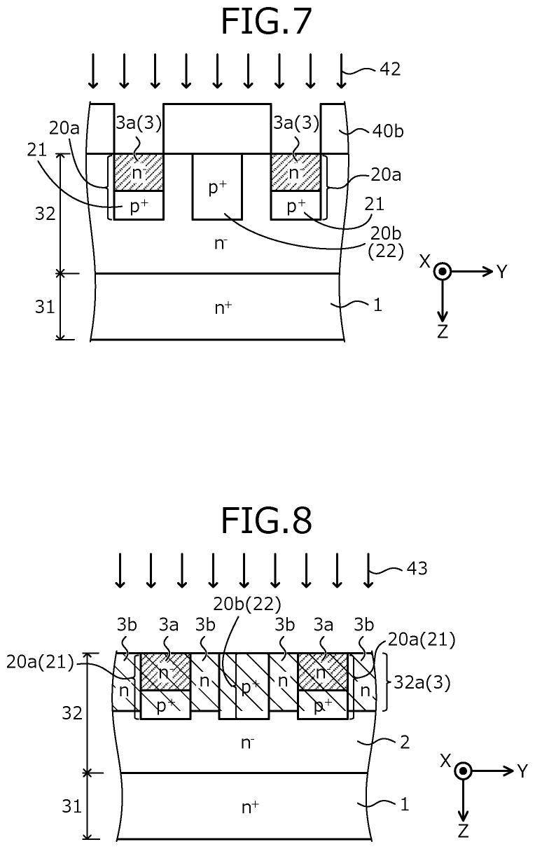

Each of the portions 20a (p⁺-type regions 20a) of the p⁺-type region 20 formed by the first ion-implantation 41 has a portion that faces the drain electrode 13 and that is constituted by one of the first p⁺-type regions 21. The p⁺-type regions 20a facing the source electrode 12 are reverted to the n⁻-type by a later-described second ion-implantation 42 (refer to FIG. 7) and thereby become first CSL portions (first current spreading regions, reverted regions) 3a. Thus, in the p-type impurity concentration distribution 41a obtained by the first ion-implantation 41, the first p⁺-type regions 21 have an impurity concentration distribution of a portion (for example, a portion extending toward the drain electrode 13 from a vicinity of the peak position 21a) that is not reverted to the n⁻-type. The second and third p⁺-type regions 22, 23 have the p-type impurity concentration distribution 41a obtained by the first ion-implantation 41.

The n-type current spreading regions 3 constitute a so-called current spreading layer (CSL). The n-type current spreading regions 3 are provided between and in contact with the first to third p⁺-type regions 21 to 23 and the p-type base region 4 and the n⁻-type drift region 2. The n-type current spreading regions 3, for example, are disposed in a matrix-like pattern in which peripheries of the n-type current spreading regions 3 are surrounded by the first to third p⁻-type regions 21 to 23 that are disposed in a lattice-like shape, as viewed from the front side of the semiconductor substrate 30 (refer to FIG. 16). The n-type current spreading regions 3 extend closer to the n⁺-type drain region 1 than are the bottoms of the trenches 7 and suffice to terminate at a depth position so as to be apart from the n⁺-type drain region 1.

The n-type current spreading regions 3 are configured by the first CSL portions 3a and second CSL portions 3b that are formed by the later-described second and third ion-implantations 42, 43 (respectively, corresponding to an N ion implantation (reversion) and an N ion implantation (CSL) in FIG. 3, refer to FIGS. 7, 8, 15, and 16). The first CSL portions 3a are regions in which the p⁻-type regions 20a that face the source are reverted to the n⁻-type by the second ion-implantation 42 and whose n-type impurity concentration is increased to an effective n-type impurity concentration by the third ion-implantation 43; the first CSL portions 3a are provided between and in contact with the p-type base region 4 and the first p⁺-type regions 21.

In the p⁺-type region 20, of the portions thereof facing the source and obtained by the first ion-implantation 41, the portions reverted to the n⁻-type by the second ion-implantation 42 are the only portions that face the first p⁺-type regions 21 in the depth direction Z. An effective n-type impurity concentration distribution of the first CSL portions 3a is an n-type impurity concentration distribution of a portion of an n-type impurity concentration distribution 43a obtained by the third ion-implantation 43, said portion does not overlap the p-type impurity concentration distribution 41a of the first p⁺-type regions 21. In the p⁺-type regions 20a, portions thereof closer to the drain electrode 13 than are the first CSL portions 3a are the first p⁺-type regions 21 (refer to FIGS. 6 and 7).

The second CSL portions (second current spreading regions) 3b are regions in which the n-type impurity concentration of portions of the n⁻-type epitaxial layer 32 is increased by the third ion-implantation 43 to have the n-type impurity concentration distribution 43a, said portions of the n⁻-type epitaxial layer 32 are free of the p⁺-type region 20 (20a, 20b, 20c) formed by the first ion-implantation 41. The n-type impurity concentration distribution 43a is a box profile in which the impurity concentration is substantially uniform in the depth direction Z. The impurity concentration being substantially uniform means the same impurity concentration, within a range that includes an allowable error due to process variation.

A set of adjacent first and second CSL portions 3a, 3b that are adjacent to one another are connected to one another and a periphery thereof is surrounded by the p⁺-type region 20 (20a, 20b, 20c) that constitutes the first to third p⁺-type regions 21 to 23. In FIG. 1, a border between an adjacent two of the first and second CSL portions 3a, 3b is indicated by a dashed line. The second CSL portions 3b of the n-type current spreading regions 3 face, in a direction parallel to the front surface of the semiconductor substrate 30, portions indicating the peak positions 21a, 22a, 23a (peak positions of the p⁺-type region 20) of the first to third p⁺-type regions 21 to 23.

The n⁺-type source regions 5 and the p⁺⁺-type contact regions 6 are each selectively provided between the front surface of the semiconductor substrate 30 and the p-type base region 4. The n⁺-type source regions 5 and the p⁺⁺-type contact regions 6 are diffused regions formed in the p-type epitaxial layer 33, at the surface of the p-type epitaxial layer 33, by ion implantation. The n⁺-type source regions 5 and the p⁺⁺-type contact regions 6 are disposed adjacent to one another in a direction parallel to the front surface of the semiconductor substrate 30, are in contact with the p-type base region 4 in the depth direction Z, and are exposed at the front surface of the semiconductor substrate 30. The p⁺⁺-type contact regions 6 may be omitted and the p-type base region 4 may be exposed at the front surface of the semiconductor substrate 30.

The trenches 7 penetrate through the n⁺-type source regions 5, the p-type base region 4, and the first CSL portions 3a, from the front surface of the semiconductor substrate 30; the trenches 7 reach the first p⁺-type regions 21, and terminate in the first p⁺-type regions 21. The first CSL portions 3a may be present between the bottoms of the trenches 7 and the first p⁺-type regions 21. In this instance, the trenches 7 penetrate through the n⁺-type source regions 5 and the p-type base region 4, from the front surface of the semiconductor substrate 30, reach the first CSL portions 3a, and terminate in the first CSL portions 3a. The first CSL portions 3a are exposed at the bottoms of the trenches 7. Gate electrodes 9 are provided in the trenches 7, respectively, via the gate insulating films 8.

Between the trenches 7 that are adjacent to one another, the p-type base region 4, the n⁺-type source regions 5, the p⁺⁺-type contact regions 6, the second p⁺-type regions 22 described above, and the n-type current spreading regions 3 are each selectively provided. The trench structure is configured by the p-type base region 4, the n⁺-type source regions 5, the p⁺⁺-type contact regions 6, the trenches 7, the gate insulating films 8, and the gate electrodes 9. Components of the trench structure, for example, are disposed in a striped pattern extending in the first direction X, which is parallel to the front surface of the semiconductor substrate 30. The n⁺-type source regions 5 and the p⁺⁺-type contact regions 6 may be scattered in the first direction X.

The interlayer insulating film 11 is provided in an entire area of the front surface of the semiconductor substrate 30 and covers the gate electrodes 9. The source electrode 12 is in contact with the n⁺-type source regions 5 and the p⁺⁺-type contact regions 6 via contact holes in the interlayer insulating film 11 and is electrically connected to the p-type base region 4, the n⁺-type source regions 5, and the p⁺⁺-type contact regions 6. In an instance in which the p⁺⁺-type contact regions 6 are omitted, the source electrode 12 is in contact with the p-type base region 4, instead of the p⁺⁺-type contact regions 6. The drain electrode (second electrode) 13 is provided in an entire area of the back surface (back surface of the n⁺-type starting substrate 31) of the semiconductor substrate 30 and is connected to the n⁺-type drain region 1.

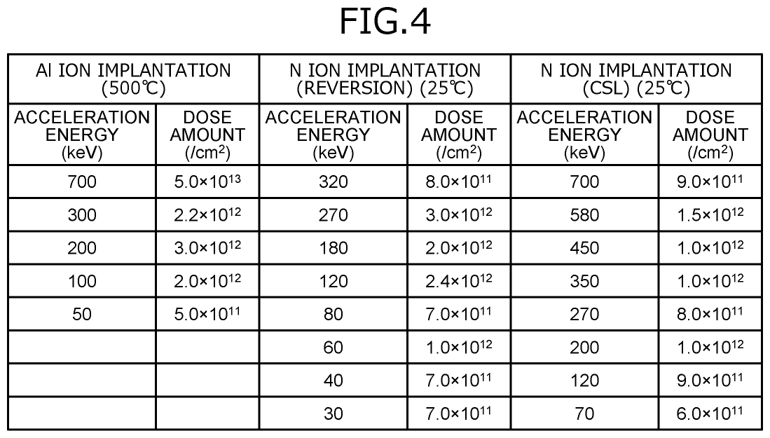

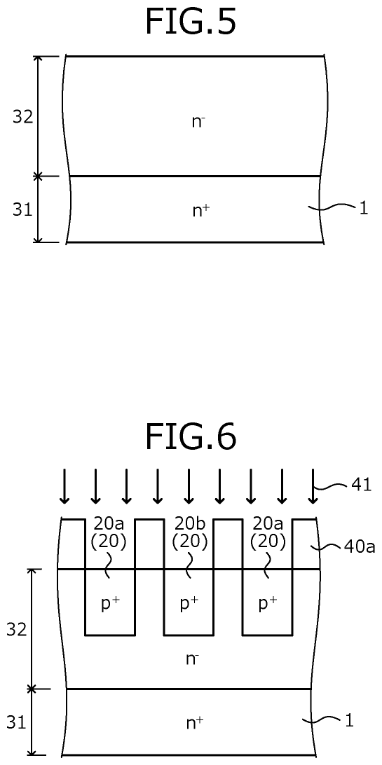

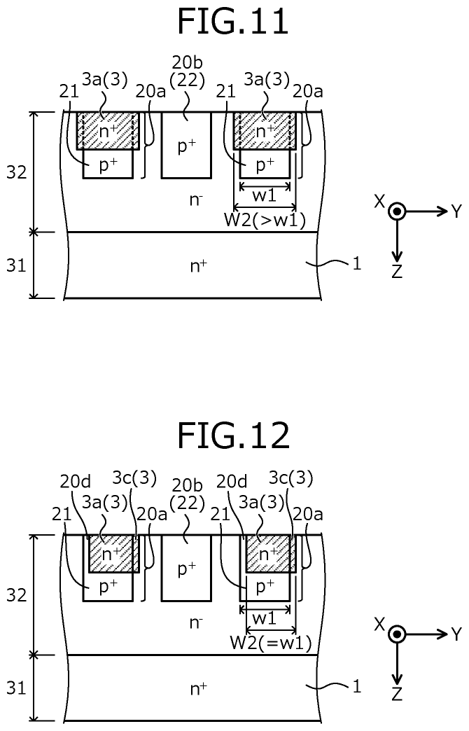

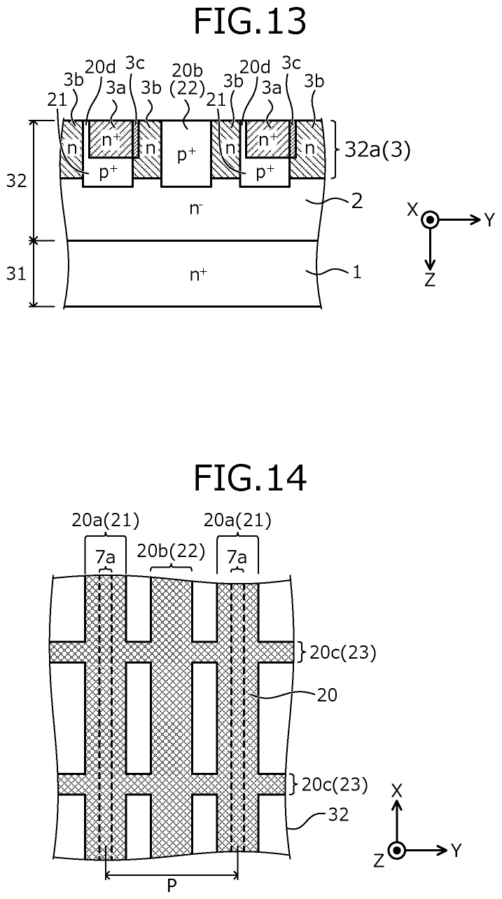

A method of manufacturing the silicon carbide semiconductor device 10 according to the first embodiment (refer to FIGS. 1 to 3) is described. FIG. 4 is a table showing an example of multistage ion implantation conditions for obtaining the impurity concentration distribution in FIG. 3. FIGS. 5, 6, 7, 8, 9, and 10 are cross-sectional views depicting states of the silicon carbide semiconductor device according to the first embodiment during manufacture. FIG. 11 is a cross-sectional view depicting another example of the state in FIG. 7 during manufacturing. FIGS. 12 and 13 are cross-sectional views depicting other examples of states of a comparison example during manufacture. FIGS. 14, 15, and 16 are plan views of the states in FIGS. 6 to 8 as viewed from an ion-implantation surface.

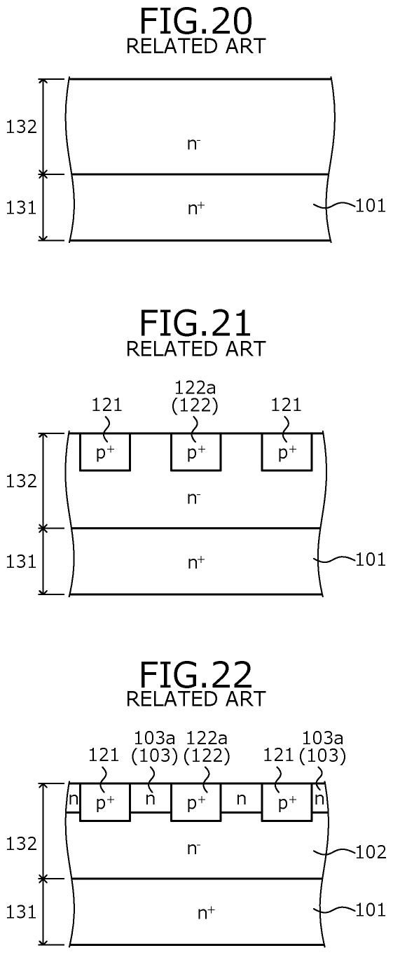

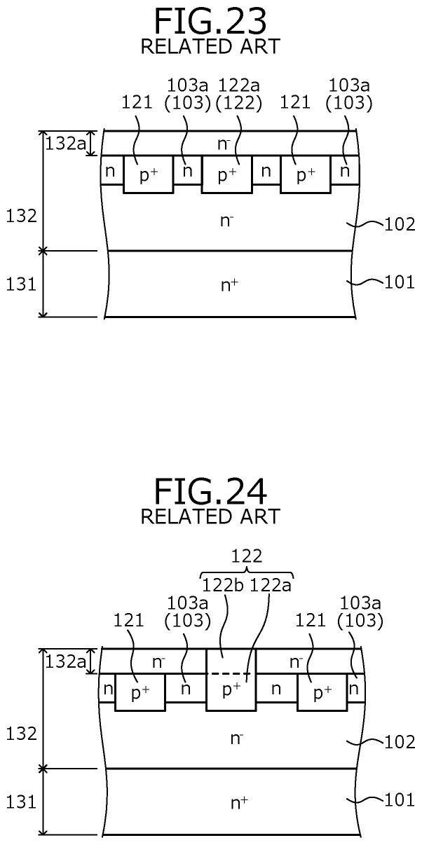

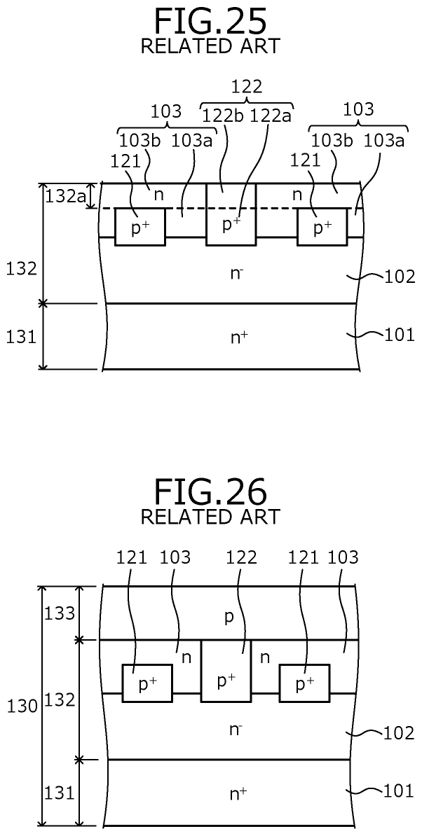

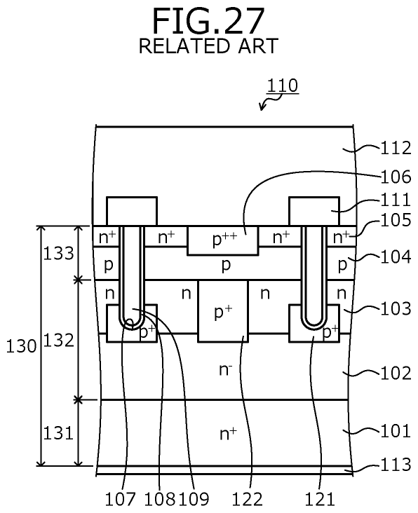

First, as depicted in FIG. 5, the n⁻-type epitaxial layer 32 constituting the n⁻-type drift region 2 is epitaxial grown on the front surface of the n⁺-type starting substrate (semiconductor wafer) 31 containing silicon carbide (first process). At this time, a thickness of the n⁻-type epitaxial layer 32 is set as a thickness equivalent to a sum of a thickness of the n⁻-type drift region 2 and a thickness of the n-type current spreading regions 3 after product (the silicon carbide semiconductor device 10) completion. Thus, unlike the method of manufacturing the conventional silicon carbide semiconductor device 110 (FIGS. 20 to 27), the thickness of the n⁻-type epitaxial layer 32 is not increased by processes hereafter.

Next, as depicted in FIG. 6, an ion implantation mask 40a opened in portions corresponding to formation regions of the first to third p⁺-type regions 21 to 23 is formed on the surface of the n⁻-type epitaxial layer 32. The ion implantation mask (including other masks used at subsequent processes), for example, is a resist film or an oxide film. Next, the first ion-implantation 41 of a p-type impurity such as aluminum is performed using the ion implantation mask 40a as a mask, thereby, selectively forming the p⁺-type region 20 (refer to FIGS. 6 and 14), which constitutes the first to third p⁺-type regions 21 to 23, in the n⁻-type epitaxial layer 32, at the surface of the n⁻-type epitaxial layer 32 (second process).

For example, of the p⁺-type region 20 formed by the first ion-implantation 41, the portions 20a that include portions that constitute the first p⁺-type regions 21 are formed in formation regions 7a of the trenches 7, the portions 20a being formed linearly in the first direction X in which the formation regions 7a of the trenches 7 extend. Of the p⁺-type region 20, the portions 20b that constitute the second p⁺-type regions 22 are formed between the formation regions 7a of the trenches 7 adjacent to one other, the portions 20b being formed linearly in the first direction X in which the formation regions 7a of the trenches 7 extend. In FIG. 14, reference character P is a cell pitch (disposal interval of the unit cells).

Of the p⁺-type region 20, the portions 20c that constitute the third p⁺-type regions 23 extend in a striped pattern in the second direction Y, which is orthogonal to the direction in which the formation regions 7a of the trenches 7 extend, the portions 20c being connected to the p⁺-type regions 20a, 20b at portions of intersection with the p⁺-type regions 20a, 20b. In other words, the p⁺-type region 20 (20a to 20c) is disposed in an a lattice-like shape as viewed from the surface of the n⁻-type epitaxial layer 32. The p⁺-type regions 20a to 20c are formed so as to reach deep depth positions closer to the drain than are the bottoms of the trenches 7 formed at the surface of the n⁻-type epitaxial layer 32 by a later process.

Next, as depicted in FIG. 7, the ion implantation mask 40a is removed and thereafter, an ion implantation mask 40b opened at portions corresponding to formation regions of the first CSL portions 3a is formed on the surface of the n⁻-type epitaxial layer 32. Next, the second ion-implantation 42 of an n-type impurity such as, for example, nitrogen is performed using the ion implantation mask 40b as a mask, thereby, reverting portions of the p⁺-type regions 20a to the n⁻-type, said portions facing the source, whereby the first CSL portions 3a are formed (first implantation process of a third process). Portions of the p⁻-type regions 20a, excluding the first CSL portions 3a (portions facing the drain electrode 13), constitute the first p⁺-type regions 21.

The second ion-implantation 42 forms the first CSL portions 3a of an n-type impurity concentration that is substantially equal to a p-type impurity concentration of portions of the p⁺-type region 20, said portions of the p⁺-type region 20 facing the source. Substantially equal impurity concentrations mean the same impurity concentration, within a range that includes an allowable error due to process variation. The p-type regions 20b, 20c (the second and third p⁻-type regions 22, 23) and portions of intersection of the p-type regions 20a and the p-type regions 20c are free of the second ion-implantation 42 (refer to FIG. 15). Thus, the first CSL portions 3a are disposed in a matrix-like pattern as viewed from the surface of the n⁻-type epitaxial layer 32.

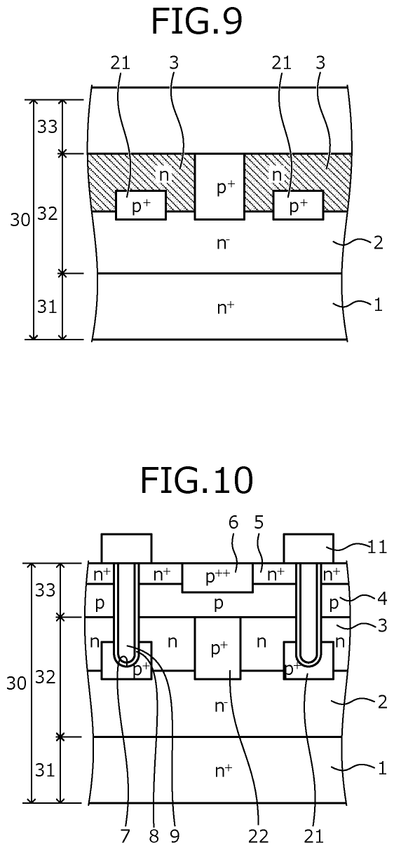

Next, as depicted in FIG. 8, the ion implantation mask 40b is removed and thereafter, an ion implantation mask (not depicted) opened in a portion corresponding to an entire area of the active region is formed on the surface of the n⁻-type epitaxial layer 3. Next, using the ion implantation mask as a mask, the third ion-implantation 43 of an n-type impurity such as, for example, nitrogen, is performed in an entire area of the surface of the n⁻-type epitaxial layer 32, in the active region, thereby forming in the n⁻-type epitaxial layer 32, at the surface of the n⁻-type epitaxial layer 32, n-type regions 32a constituting the n-type current spreading regions 3 (second implantation process of the third process). The first to third p⁺-type regions 21 to 23 have impurity concentrations that are higher than that of the n-type regions 32a and thus, even after the third ion-implantation 43, a predetermined p-type impurity concentration remains (refer to FIG. 9).

The n-type impurity concentration of the first CSL portions 3a (regions reverted to the n⁻-type) is increased to a predetermined n-type impurity concentration of the n-type current spreading regions 3 by the n-type regions 32a (refer to FIG. 3) and in the n⁻-type epitaxial layer 32, at the surface of the n⁻-type epitaxial layer 32, portions other than the p⁺-type region 20 form the second CSL portions 3b. The first and second CSL portions 3a, 3b have substantially the same n-type impurity concentration. Any adjacent two of the second CSL portions 3b adjacent to each other in the second direction Y with one of the formation regions 7a of the trenches 7 intervening therebetween, are connected to each other by the first CSL portions 3a formed in the formation regions 7a of the trenches 7 (refer to FIG. 16).

In other words, surface regions (formation regions of the trenches 7) of the p⁺-type regions 20a are reverted to the n⁻-type by the second ion-implantation 42, whereby the first CSL portions 3a are formed and the effective n-type impurity concentration of the first CSL portions 3a is set to be substantially the same as the n-type impurity concentration of the n⁻-type epitaxial layer 32. Further, the n-type impurity concentration of the first CSL portions 3a and the n-type impurity concentration of surface regions (the second CSL portions 3b) of the n⁻-type epitaxial layer 32, excluding the p⁺-type region 20, are increased by the third ion-implantation 43 to predetermined n-type impurity concentrations.

In this manner, the n-type current spreading regions 3 that are constituted by the first and second CSL portions 3a, 3b of substantially the same n-type impurity concentration may be formed by the second and third ion-implantations 42, 43. A portion of the n⁻-type epitaxial layer 32, excluding the first to third p⁺-type regions 21 to 23 and the n-type current spreading regions 3, constitutes the n⁻-type drift region 2. Next, as depicted in FIG. 9, the ion implantation mask used in the formation of the n-type regions 32a is removed and thereafter, the p-type epitaxial layer 33 that constitutes the p-type base region 4 is epitaxially grown on the n⁻-type epitaxial layer 32 (fourth process).

In this manner, the semiconductor substrate (semiconductor wafer) 30 in which the n⁻-type epitaxial layer 32 and the p-type epitaxial layer 33 are sequentially stacked on the n⁺-type starting substrate 31 is formed. As described, the semiconductor substrate 30 is formed by the five (5) processes, from the process of epitaxially growing the n⁻-type epitaxial layer 32 to the process of epitaxially growing the p-type epitaxial layer 33 (epitaxial growth of the n⁻-type epitaxial layer 32, the first to third in implantations 41 to 43, and the epitaxial growth of the p-type epitaxial layer 33).

Next, as depicted in FIG. 10, by a general method, in the front side of the semiconductor substrate 30, the MOS gates are formed constituted by the n⁺-type source regions 5, the p⁺⁺-type contact regions 6, the trenches 7, the gate insulating films 8, and the gate electrodes 9, the interlayer insulating film 11, the source electrode 12, and the drain electrode 13 are also formed (fifth process). Portions of the p-type epitaxial layer 33, excluding the n⁺-type source regions 5 and the p⁺⁺-type contact regions 6, is the p-type base region 4. Subsequently, the semiconductor substrate 30 is cut (diced) into individual chips, whereby the SiC-MOSFET depicted in FIG. 1 is completed.

The first to third ion-implantations 41 to 43 may be multistage ion implantation in which ion implantation is divided into multiple stages (multiple sessions) that are performed using different acceleration energies so that a predetermined total dose amount is achieved. Examples of multistage ion implantation conditions (acceleration energy, dose amount) for the first to third ion-implantations 41 to 43 (Al ion implantation, the N ion implantation (reversion), and the N ion implantation (CSL)) are depicted in FIG. 4. Conditions for each stage in an instance in which the first to third ion-implantations 41 to 43 are divided into 5 stages, 8 stages, and 8 stages, respectively, are indicated in a single row (in FIG. 4, number of rows=number of stages). Temperatures of the semiconductor substrate 30 during the first to third ion-implantations 41 to 43 may be about 500 degrees C., about room temperature (25 degrees C.), and about room temperature, respectively.

The first ion-implantation 41 obtains the p-type impurity concentration distribution 41a in which the peak positions 21a, 22a, 23a of a peak concentration of, for example, at least about 1×10¹⁸/cm³ are deep positions closer to the drain than are the bottoms of the trenches 7. In the p-type impurity concentration distribution 41a obtained by the first ion-implantation 41, at least an impurity concentration of a portion thereof overlapping an n-type impurity concentration distribution 42a obtained by the second ion-implantation 42 suffices to be substantially uniform in the depth direction Z, for example, in a range of about 1×10¹⁷/cm³ to 4×10¹⁷/cm³ (refer to FIG. 3).

In the p-type impurity concentration distribution 41a obtained by the first ion-implantation 41, the impurity concentration of the portion thereof overlapping the n-type impurity concentration distribution 42a obtained by the second ion-implantation 42 is set to be within the range described above for the following reasons. As depicted in FIG. 11, with consideration of the accuracy of the positioning of the ion implantation mask 40b used in the second ion-implantation 42, a width w2 of the first CSL portions 3a may be at least equal to a width w1 of portions (the p⁺-type regions 20a) reverted to the n⁻-type by the second ion-implantation 42 and may be wider than the width w1, extending beyond each side of the p⁺-type regions 20a in the second direction Y by not more than about 0.1 μm.

Assuming an instance in which, as depicted in FIGS. 12 and 13, the positions of the first CSL portions 3a are shifted in the second direction Y (here, for example, w1=w2), as described later, the n-type impurity concentration of the n-type regions 32a obtained by the third ion-implantation 43 is lower than the p-type impurity concentration of the p⁺-type region 20 obtained by the first ion-implantation 41 and therefore, in each of the p⁺-type regions 20a, the first CSL portion 3a therein and one (for example, the one on the left-side) of two of the second CSL portions 3b, respectively formed at the sides of the first CSL portion 3a in the second direction Y are fragmented by a portion 20d of the p⁻-type regions 20a, the portion 20d, which is not reverted to the n⁻-type.

In addition, when the positions of the first CSL portions 3a in the second direction Y are shifted, the n-type impurity concentration of the n-type current spreading regions 3 becomes relatively high due to a portion (end portion on the right-side) 3c of each of the first CSL portions 3a, the portion 3c, which does not overlap the p⁺-type regions 20a. Thus, so that the n-type impurity concentration of the n-type current spreading regions 3 does not become extremely high due to the portions 3c, in each of the p⁺-type regions 20a, the p-type impurity concentration of the portions (formation regions of the first CSL portions 3a) thereof that are reverted to the n⁻-type may be preferably set to be in a range of about 1×10¹⁷/cm³ to 4×10¹⁷/cm³ as described above and the dose amount of the second ion-implantation 42 may be set low.

In the p-type impurity concentration distribution 41a obtained by the first ion-implantation 41, a depth (that is, the depth of the first CSL portions 3a) of the portion thereof that overlaps the n-type impurity concentration distribution 42a obtained by the second ion-implantation 42 is, for example, about 0.3 μm from the surface (that is, a pn junction interface between the p-type base region and the n-type current spreading region) of the n⁻-type epitaxial layer 32. The second ion-implantation 42, at a portion that overlaps the p-type impurity concentration distribution 41a obtained by the first ion-implantation 41, obtains the n-type impurity concentration distribution 42a, which is substantially the same impurity concentration distribution as the p-type impurity concentration distribution 41a (refer to FIG. 3).

In other words, the second ion-implantation 42, for example, by an n-type impurity concentration in a range of about 1×10¹⁷/cm³ to 4×10¹⁷/cm³, reverts to the n⁻-type, a portion of the p⁺-type region 20, facing the source. The n-type impurity concentration (that is, the n-type impurity concentration of the n-type current spreading regions 3) of the n-type impurity concentration distribution 43a obtained by the third ion-implantation 43 is, for example, at least about 1×10¹⁷/cm³, is lower than the p-type impurity concentration of the p-type impurity concentration distribution 41a obtained by the first ion-implantation 41, and is lower than the n-type impurity concentration of the n-type impurity concentration distribution 42a obtained by the second ion-implantation 42 (refer to FIG. 3).

As described above, according to the first embodiment, in the n⁻-type epitaxial layer that constitutes the n⁻-type drift region, at the surface thereof, after the p⁺-type regions that constitute the first and second p⁺-type regions that mitigate electric field applied to the bottoms of the trenches are formed in a striped pattern by the first ion-implantation of a p-type impurity, by the second ion-implantation of an n-type impurity, portions of the p⁺-type regions are reverted to the n⁻-type of an n-type impurity concentration that is equal to the p-type impurity concentration of portions of the p⁺-type regions, and the first CSL portions that constitute the n-type current spreading regions are formed at positions that face the first p⁺-type regions in the depth direction.

Thereafter, by the third ion-implantation of an n-type impurity, the n-type impurity concentration of the first CSL portions is increased and the second CSL portions that are in contact with the first CSL portions are formed between the p⁺-type regions, whereby the n-type current spreading region constituted by the first and second CSL portions is formed. The n-type impurity concentration of the third ion-implantation is lower than the p-type impurity concentration of the first ion-implantation, whereby, excluding the first CSL portions, portions of the p⁺-type regions formed by the first ion-implantation are left as the first and second p⁺-type regions. A portion of the n⁻-type epitaxial layer free of the first to third ion-implantations constitutes the n⁻-type drift region.

In this manner, the first and second p⁺-type regions and the n-type current spreading regions are formed, whereby by a single session of epitaxial growth, the n⁻-type epitaxial layer may be formed having a predetermined final product thickness. Thus, processes for increasing the thickness of the n⁻-type epitaxial layer during manufacture like those of the conventional method are unnecessary, the processes from the epitaxial growth of the n⁻-type epitaxial layer that constitutes the n⁻-type drift region, to the epitaxial growth of the p-type epitaxial layer constituting the p-type base region include five processes and thus, the number of processes may be reduced as compared to the conventional method (refer to FIGS. 20 to 27).

Further, according to the first embodiment, the number of processes is reduced to five processes including the two sessions of the epitaxial process for depositing the epitaxial layers that constitute the n⁻-type drift region and the p-type base region, the one session of the multistage ion implantation (first ion-implantation) for forming the first and second p⁺-type regions, and the two sessions of the multistage ion implantation (second and third ion-implantations) for forming the n-type current spreading regions, whereby the lead-time may be shortened as compared to the conventional method (seven processes including three sessions of the epitaxial process and four sessions of the multistage ion implantation).

Next, a method of manufacturing a silicon carbide semiconductor device according to a second embodiment is described. FIGS. 17, 18, and 19 are cross-sectional views depicting states of the silicon carbide semiconductor device according to the second embodiment during manufacture. The method of manufacturing the silicon carbide semiconductor device according to the second embodiment differs from the method of manufacturing the silicon carbide semiconductor device 10 according to the first embodiment in that instead of the third ion-implantation 43 (refer to FIG. 8), an n-type epitaxial layer (first-conductivity-type epitaxial layer) 51 of a two-layer structure having different n-type impurity concentrations is epitaxially grown. The structure of the silicon carbide semiconductor device according to the second embodiment is similar to that of the silicon carbide semiconductor device 10 according to the first embodiment (refer to FIGS. 1 to 4).

In the second embodiment, first, as depicted in FIG. 17, on the front surface of the n⁺-type starting substrate (semiconductor wafer) 31 that contains silicon carbide, epitaxial growth of the epitaxial layer 51 (52: first first-conductivity-type epitaxial layer) of the impurity concentration of the n⁻-type drift region 2 is started and at the point when the thickness thereof becomes a final product thickness of the n⁻-type drift region 2, the impurity concentration is changed to that of the n-type current spreading regions 3 and the epitaxial growth is continued, whereby the epitaxial layer 51 (53: second first-conductivity-type epitaxial layer) is epitaxially grown. A total thickness of the epitaxial layer 51 is equal to the thickness of the n⁻-type epitaxial layer 32 (refer to FIG. 5) of the first embodiment.

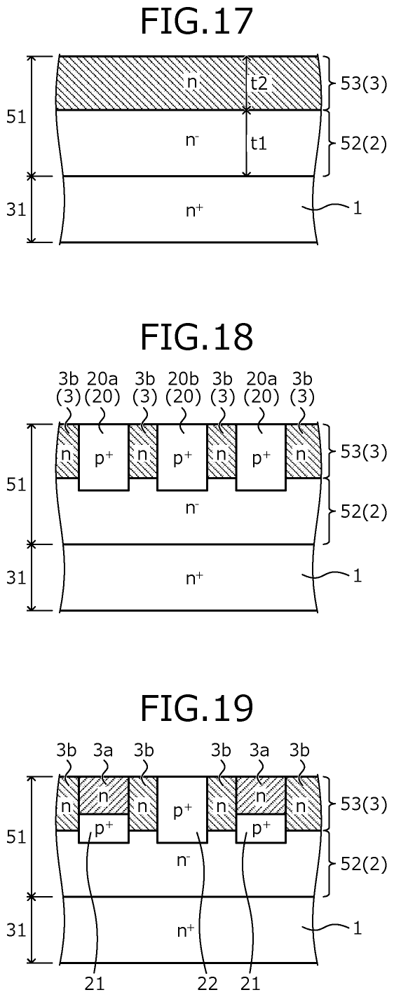

Next, as depicted in FIG. 18, similarly to the first embodiment, the first ion-implantation 41 is performed, whereby the p⁺-type region 20 constituting the first to third p⁺-type regions 21 to 23 is formed. The p-type impurity concentration of the p⁺-type region 20 formed by the first ion-implantation 41 is higher than the n-type impurity concentration of the epitaxial layer 51 (52, 53). Thus, the n-type current spreading regions 3 are fragmented by the p⁺-type region 20 (20a to 20c) and, similarly to the first embodiment, the n-type current spreading regions 3 are left in a matrix-like pattern in which the peripheries of the n-type current spreading regions 3 are surrounded by the p⁺-type region 20, which is disposed in a lattice-like shape as viewed from the surface of the epitaxial layer 5. The fragmented n-type current spreading regions 3 constitute the second CSL portions 3b.

Next, as depicted in FIG. 19, similarly to the first embodiment, the second ion-implantation 42 is performed, whereby portions of the p⁺-type region 20 are reverted to the n⁻-type, thereby forming the first CSL portions 3a. As a result, similarly to the first embodiment, the n-type current spreading regions 3 are formed in which the first and second CSL portions 3a, 3b are connected and portions of the p⁺-type region 20, excluding the first CSL portions 3a, constitute the first to third p⁺-type regions 21 to 23. Thereafter, similarly to the first embodiment, the process of epitaxially growing the p-type epitaxial layer 33 constituting the p-type base region 4 and subsequent processes (refer to FIGS. 9 and 10) are sequentially performed, whereby the SiC-MOSFET depicted in FIG. 1 is completed.

The semiconductor substrate 30 is formed by the four processes (the epitaxial growth of the n-type epitaxial layer 51, the first and second ion-implantations 41, 42, and the epitaxial growth of the p-type epitaxial layer 33) from the process of epitaxially growing the n-type epitaxial layer 51 constituting the n⁻-type drift region 2 and the n-type current spreading regions 3, to the process of epitaxially growing the p-type epitaxial layer 33 that constitutes the p-type base region 4. A thickness t1 of the n⁻-type drift region 2 (the n⁻-type epitaxial layer 52) is, for example, about 10 μm, whereas a thickness t2 of the n-type current spreading regions 3 (the n-type epitaxial layer 53) is, for example, about 1 μm.

As described above, according to the second embodiment, the n-type impurity concentration of the epitaxial layer is adjusted, whereby even when the effective n-type impurity concentration of the portion that constitutes the n-type current spreading region is adjusted, an effect similar to that of the first embodiment may be obtained.

In the foregoing, the present invention is not limited to the embodiments described above and various modifications within a range not departing from the spirit of the invention are possible. For example, in the first embodiment described above, the first to third ion-implantations may be performed between the epitaxial growth of the n⁻-type epitaxial layer that constitutes the n⁻-type drift region and the epitaxial growth of the p-type epitaxial layer that constitutes the p-type base region, and the sequence in which the first to third ion-implantations are performed may be interchanged.

As described above, the first-conductivity-type epitaxial layer may be formed to have a predetermined final product thickness by a single session of epitaxial growth. Thus, processes for increasing the thickness of the first-conductivity-type epitaxial layer during manufacture like those of the conventional method are unnecessary, the process from the epitaxial growth of the first-conductivity-type epitaxial layer constituting the n⁻-type drift region (first semiconductor region), to the epitaxial growth of the second-conductivity-type epitaxial layer constituting the p-type base region (second semiconductor region) are reduced to five processes.

The silicon carbide semiconductor device and the method of manufacturing a silicon carbide semiconductor device according to the present invention achieve an effect in that the number of processes may be reduced.

As described, the silicon carbide semiconductor device and the method of manufacturing a silicon carbide semiconductor device according to the present invention are useful for power semiconductor devices used in power converting equipment, power source devices of various types of industrial machines, etc.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A method of manufacturing a vertical silicon carbide semiconductor device having a trench structure, the method comprising:
as a first process,
preparing a starting substrate that contains silicon carbide, the starting substrate having a main surface, and
forming a first-conductivity-type epitaxial layer, which is an epitaxial layer of a first conductivity type, on the main surface of the starting substrate, the first-conductivity-type epitaxial layer having a first surface and a second surface that are opposite to each other, the second surface facing the starting substrate;
as a second process,
performing a first ion-implantation of an impurity of a second conductivity type and thereby forming, in the first-conductivity-type epitaxial layer, a plurality of second-conductivity-type high-concentration regions at the first surface of the first-conductivity-type epitaxial layer;
as a third process,
forming, in the first-conductivity-type epitaxial layer, a plurality of current spreading regions of the first conductivity type at the first surface of the first-conductivity-type epitaxial layer, the plurality of current spreading regions reducing carrier spreading resistance and having an impurity concentration that is higher than an impurity concentration of the first-conductivity-type epitaxial layer;
as a fourth process,
forming a second-conductivity-type epitaxial layer, which is an epitaxial layer of a second conductivity type, on the first surface of the first-conductivity-type epitaxial layer, after forming the plurality of second-conductivity-type high-concentration regions and the plurality of current spreading regions; and
as a fifth process,
forming the trench structure in the second-conductivity-type epitaxial layer, the trench structure including a plurality of trenches, wherein
the plurality of second-conductivity-type high-concentration regions includes a plurality of first second-conductivity-type high-concentration regions and a plurality of second second-conductivity-type high-concentration regions;
the second process includes:
forming the plurality of first second-conductivity-type high-concentration regions respectively in a plurality of formation regions of the plurality of trenches, each of the plurality of first second-conductivity-type high-concentration regions reaching a first position that is closer to the starting substrate than are the plurality of trenches, and having a first surface and a second surface that are opposite to each other, the second surface thereof facing the starting substrate, and
forming the plurality of second second-conductivity-type high-concentration regions, each between adjacent two of the plurality of formation regions of the plurality of trenches and reaching a second position that is closer to the starting substrate than are the plurality of trenches;
the plurality of current spreading regions includes a plurality of first current spreading regions and a plurality of second current spreading regions;
the third process includes:
as a first implantation process,
performing a second ion-implantation of an impurity of the first conductivity type and thereby increasing, in the plurality of first second-conductivity-type high-concentration regions, a first-conductivity-type impurity concentration of surface portions at the first surfaces of the plurality of first second-conductivity-type high-concentration regions to be higher than a second-conductivity-type impurity concentration thereof, thereby forming the plurality of first current spreading regions, each of the plurality of first current spreading regions being formed between the first surface of the first-conductivity-type epitaxial layer and a remaining portion of each of the plurality of first second-conductivity-type high-concentration regions, the remaining portion being free of the second ion-implantation, and
as a second implantation process,
performing a third ion-implantation of the impurity of the first conductivity type in an entire area of the first surface of the first-conductivity-type epitaxial layer, thereby
increasing the first-conductivity-type impurity concentration of the surface portions that constitute the plurality of first current spreading regions, to be higher than the second-conductivity-type impurity concentration, and
further forming the plurality of second current spreading regions in the first-conductivity-type epitaxial layer, in portions thereof at the first surface of the first-conductivity-type epitaxial layer, excluding the plurality of second-conductivity-type high-concentration regions and the plurality of first current spreading regions, the plurality of second current spreading regions being in contact with the plurality of first current spreading regions.

2. The method of manufacturing according to claim 1, wherein
the first process, the second process, the third process, the fourth process, and the fifth process are performed sequentially, in a sequence of the first process, the second process, the third process, the fourth process, and the fifth process.

3. The method of manufacturing according to claim 1, wherein
the first process, the second process, the third process, the fourth process, and the fifth process are performed sequentially, in a sequence of the first process, the third process, the second process, the fourth process, and the fifth process.

4. The method of manufacturing according to claim 1, wherein
in the third process, the first-conductivity-type impurity concentration is set in a range of 1×10¹⁷/cm³ to 4×10¹⁷/cm³ by the second ion-implantation, and the surface portions of the plurality of first second-conductivity-type high-concentration regions are reverted to be of the first conductivity type.

5. The method of manufacturing according to claim 1, wherein in the third process,
the surface portions of the plurality of first second-conductivity-type high-concentration regions are reverted to be of the first conductivity type by the second ion-implantation, and
the first-conductivity-type impurity concentration of the plurality of second current spreading regions formed by the third ion-implantation is lower than the first-conductivity-type impurity concentration of the surface portions reverted by the second ion-implantation.

6. The method of manufacturing according to claim 5, wherein
in the third process, the first-conductivity-type impurity concentration of the plurality of second current spreading regions is at least 1×10¹⁷/cm³.

7. The method of manufacturing according to claim 4, wherein
in the second process, the surface portions of the plurality of first second-conductivity-type high-concentration regions reverted to the first conductivity type by the second ion-implantation have a second-conductivity-type impurity concentration that is in a range of 1×10¹⁷/cm³ to 4×10¹⁷/cm³.

8. The method of manufacturing according to claim 4, wherein
in the second process, in the plurality of first second-conductivity-type high-concentration regions, portions thereof from the first surface of the first-conductivity-type epitaxial layer to a depth of at least 0.3 μm have a second-conductivity-type impurity concentration in a range of 1×10¹⁷/cm³ to 4×10¹⁷/cm³, and
in the third process, in the plurality of first second-conductivity-type high-concentration regions, the portions thereof from the first surface of the first-conductivity-type epitaxial layer to the depth of at least 0.3 μm are reverted to the first conductivity type by the second ion-implantation.

9. The method of manufacturing according to claim 1, wherein
in the second process, the plurality of second-conductivity-type high-concentration regions is formed having a second-conductivity-type impurity concentration distribution in which an impurity concentration at a position closer to the starting substrate than are the bottoms of the plurality of trenches is at least 1×10¹⁸/cm³.

10. The method of manufacturing according to claim 1, wherein
in the third process, only the surface portions of the first second-conductivity-type high-concentration regions are reverted to the first conductivity type by the second ion-implantation.

11. The method of manufacturing according to claim 1, wherein
in the third process, each of the plurality of first current spreading regions extends beyond one of the plurality of first second-conductivity-type high-concentration regions by not more than 0.1 μm in a direction parallel to the first surface of the first-conductivity-type epitaxial layer.

12. A method of manufacturing a vertical silicon carbide semiconductor device having a trench structure, the method comprising:
as a first process,
preparing a starting substrate that contains silicon carbide, the starting substrate having a main surface, and
forming a first-conductivity-type epitaxial layer, which is an epitaxial layer of a first conductivity type, on the main surface of the starting substrate, the first-conductivity-type epitaxial layer having a first surface and a second surface that are opposite to each other, the second surface facing the starting substrate;
as a second process,
performing a first ion-implantation of an impurity of a second conductivity type and thereby forming, in the first-conductivity-type epitaxial layer, a plurality of second-conductivity-type high-concentration regions at the first surface of the first-conductivity-type epitaxial layer;
as a third process,
forming, in the first-conductivity-type epitaxial layer, a plurality of current spreading regions of the first conductivity type at the first surface of the first-conductivity-type epitaxial layer, the plurality of current spreading regions reducing carrier spreading resistance and having an impurity concentration that is higher than an impurity concentration of the first-conductivity-type epitaxial layer;
as a fourth process,
forming a second-conductivity-type epitaxial layer, which is an epitaxial layer of a second conductivity type, on the first surface of the first-conductivity-type epitaxial layer, after forming the plurality of second-conductivity-type high-concentration regions and the plurality of current spreading regions; and
as a fifth process,
forming the trench structure in the second-conductivity-type epitaxial layer, the trench structure including a plurality of trenches, wherein
the first process includes:
sequentially stacking a first first-conductivity-type epitaxial layer and a second first-conductivity-type epitaxial layer, which constitutes the plurality of current spreading regions and has an impurity concentration that is higher than an impurity concentration of the first first-conductivity-type epitaxial layer, thereby forming the first-conductivity-type epitaxial layer;
the second process includes:
forming, as the plurality of second-conductivity-type high-concentration regions, a plurality of first second-conductivity-type high-concentration regions and a plurality of second second-conductivity-type high-concentration regions, each of the plurality of first second-conductivity-type high-concentration regions being formed in one of a plurality of formation regions of the plurality of trenches and reaching a first position closer to the starting substrate than are the plurality of trenches, and each of the plurality of second second-conductivity-type high-concentration regions being formed between adjacent two of the plurality of formation regions of the plurality of trenches and reaching a second position closer to the starting substrate than are the plurality of trenches; and
the third process includes:
reverting surface portions of the first second-conductivity-type high-concentration regions to the first conductivity type, thereby forming a plurality of reverted regions of the first conductivity type, each of the plurality of reverted regions being formed between the first surface of the first-conductivity-type epitaxial layer and a remaining portion of one of the plurality of first second-conductivity-type high-concentration regions, the plurality of current spreading regions fragmented by the plurality of first second-conductivity-type high-concentration regions in the second process being connected by the plurality of reverted regions.

13. A silicon carbide semiconductor device, comprising:
a semiconductor substrate containing silicon carbide and having a first main surface and a second main surface that are opposite to each other;
a first semiconductor region of a first conductivity type, provided in the semiconductor substrate;
a second semiconductor region of a second conductivity type, provided between the first main surface of the semiconductor substrate and the first semiconductor region;
a plurality of third semiconductor regions of the first conductivity type, selectively provided between the first main surface of the semiconductor substrate and the second semiconductor region;
a plurality of current spreading regions of the first conductivity type, provided between the second semiconductor region and the first semiconductor region, the plurality of current spreading regions reducing carrier spreading resistance and having an impurity concentration that is higher than an impurity concentration of the first semiconductor region;
a plurality of trenches penetrating through the plurality of third semiconductor regions and the second semiconductor region, and reaching the plurality of current spreading regions;
a plurality of gate electrodes provided in the plurality of trenches, respectively, via a plurality of gate insulating films;
a first electrode electrically connected to the plurality of third semiconductor regions and the second semiconductor region;
a second electrode provided on the second main surface of the semiconductor substrate; and
a plurality of second-conductivity-type high-concentration regions selectively provided in the semiconductor substrate, the plurality of second-conductivity-type high-concentration regions reaching a depth closer to the second electrode than are bottoms of the plurality of trenches and having an impurity concentration higher than an impurity concentration of the second semiconductor region, wherein
the plurality of second-conductivity-type high-concentration regions includes
a plurality of first second-conductivity-type high-concentration regions, facing the bottoms of the plurality of trenches in a depth direction of the silicon carbide semiconductor device, and
a plurality of second second-conductivity-type high-concentration regions provided in contact with the second semiconductor region but apart from the plurality of first second-conductivity-type high-concentration regions and the plurality of trenches,
a second-conductivity-type impurity concentration of the plurality of second-conductivity-type high-concentration regions has a maximum value at a position closer to the second electrode than are the bottoms of the plurality of trenches, and
each of the plurality of current spreading regions has a first portion between the second semiconductor region and one of the plurality of first second-conductivity-type high-concentration regions, the first portion containing an impurity of the second conductivity type, and having a second-conductivity-type impurity concentration that is a same as a second-conductivity-type impurity concentration of the plurality of second second-conductivity-type high-concentration regions at a same depth in a direction from the second semiconductor region to the second electrode.

14. The silicon carbide semiconductor device according to claim 13, wherein
the second-conductivity-type impurity concentration of the plurality of second second-conductivity-type high-concentration regions is in a range of 1×10¹⁷/cm³ to 4×10¹⁷/cm³ at a portion facing the first portions of the plurality of current spreading regions in a direction parallel to the first main surface of the semiconductor substrate,
the first portions of the plurality of current spreading regions include an impurity of the second conductivity type, and have a second-conductivity-type impurity concentration in a range of 1×10¹⁷/cm³ to 4×10¹⁷/cm³, and
the first portion of the plurality of current spreading regions have an effective first-conductivity-type impurity concentration that is at least 1×10¹⁷/cm³.

15. The silicon carbide semiconductor device according to claim 13, wherein
each of the plurality of current spreading regions has a second portion in addition to the first portion, the second portion having a first-conductivity-type impurity concentration that is at least 1×10¹⁷/cm³.

16. The silicon carbide semiconductor device according to claim 13, wherein
the impurity concentration of the plurality of second-conductivity-type high-concentration regions is at least 1×10¹⁸/cm³ at a position closer to the second electrode than are the bottoms of the plurality of trenches.
